(19) United States
(12) Patent Application Publication
(10) Pub. No.: US 2026/0255803 A1
(43) Pub. Date: Aug. 27, 2026

(54) DISPLAY PANEL AND DISPLAY APPARATUS

(71) Applicant: Guangzhou China Star Optoelectronics Semiconductor Display Technology Co., LTd., Guangzhou (CN)

(72) Inventors: Weiran CAO, Guangzhou (CN); Juncheng XIAO, Guangzhou (CN); Yuanjun HSU, Guangzhou (CN); Shan LI, Guangzhou (CN); Yunxi LIU, Guangzhou (CN); Xiaoxing ZHANG, Guangzhou (CN)

(73) Assignee: Guangzhou China Star Optoelectronics Semiconductor Display Technology Co., LTd., Guangzhou (CN)

(21) Appl. No.: 19/249,571

(22) Filed: Jun. 25, 2025

(30) Foreign Application Priority Data
Feb. 26, 2025 (CN) 202510220206.3

(51) Int. Cl. H10K 59/121; H10K 59/124

(52) U.S. Cl. CPC H10K 59/1216; H10K 59/124

(57) ABSTRACT

The present disclosure provides a display apparatus and a display panel. The display panel includes a substrate, a thin film transistor and a capacitor structure disposed on the substrate, a first insulating layer covering the thin film transistor and located between first and electrode plates of the capacitor structure, a first planarization layer covering the first insulating layer, a second planarization layer covering the first planarization layer, and an anode. A thickness of the first insulating layer corresponding to the first electrode plate is less than a thickness of the first insulating layer corresponding to the thin film transistor. The first planarization layer has a first opening corresponding to the first electrode plate, and the second electrode plate is filled in the first opening. The second planarization layer fills the first opening. The anode is electrically connected to the thin film transistor and partially overlaps the capacitor structure.

### CROSS-REFERENCE TO RELATED APPLICATION

This application claims priority to Chinese Patent Application No. 202510220206.3, filed on Feb. 26, 2025. The disclosure of the aforementioned application is incorporated herein by reference in its entirety.

### TECHNICAL FIELD

The present disclosure relates to the field of display technologies, and in particular to, a display panel and a display apparatus.

### BACKGROUND

Ink-jet printing OLED technology has extremely high requirements for the flatness of the terrain of pixels. If a terrain segment difference of the pixels is relative large, the uniformity of a dry film thickness formed by the luminescent material ink after drying will be poor, which will lead to uneven luminous brightness of the pixels and poor luminous efficiency of the device.

In the course of research and practice of prior arts, the inventors of the present disclosure have found that a pixel area of the ink-jet printing OLED in the prior art will cover a capacitance area with a large electrode plate area. Due to the requirements of high refresh rate and high resolution, a capacitor structure generally adopts a plurality of conductive film layers to improve its capacitance value, which leads to a high terrain of the film layers in the capacitance area below the pixel area, causing the capacitance area and other areas in the pixel area to form a large terrain segment difference extreme value, and then affecting the flatness of the pixels.

### SUMMARY

Embodiments of the present disclosure provide a display panel. The display panel includes a pixel area configured to emit light, and the display panel includes:

a substrate;

a thin film transistor disposed on the substrate;

a capacitor structure disposed on the substrate, at least a portion of the capacitor structure being located within the pixel area, the capacitor structure including a first electrode plate and a second electrode plate disposed in different layers, and the second electrode plate being located on one side of the first electrode plate away from the substrate;

a first insulating layer covering the thin film transistor and located between the first electrode plate and the second electrode plate, a thickness of the first insulating layer at a position corresponding to the first electrode plate being less than a thickness of the first insulating layer at a position corresponding to the thin film transistor;

a first planarization layer covering the first insulating layer, the first planarization layer having a first opening corresponding to the first electrode plate, the second electrode plate being filled in the first opening, and a thickness of the second electrode plate being less than or equal to a depth of the first opening;

a second planarization layer covering the first planarization layer and the second electrode plate and filling the first opening; and

an anode disposed on one side of the second planarization layer away from the substrate and electrically connected to the thin film transistor, the anode partially overlapping the capacitor structure in a thickness direction of the display panel.

Embodiments of the present disclosure also provide a display apparatus including the above display panel.

### BRIEF DESCRIPTION OF THE DRAWINGS

FIG. 1 is a schematic diagram of a display device according to embodiments of the present disclosure.

FIG. 2 is an enlarged view of portion A in FIG. 1.

FIG. 3 is a schematic diagram of a connection between a second electrode plate and a third electrode plate in a display panel according to embodiments of the present disclosure.

FIG. 4 is a schematic diagram of a structure corresponding to a step B105 of a manufacturing method of a display panel according to embodiments of the present disclosure.

FIG. 5 is a schematic diagram of a structure corresponding to a step B106 of a manufacturing method of a display panel according to embodiments of the present disclosure.

FIG. 6 is a schematic diagram of a structure corresponding to a step B107 of a manufacturing method of a display panel according to embodiments of the present disclosure.

FIG. 7 is a schematic diagram of a structure corresponding to a step B108 of a manufacturing method of a display panel according to embodiments of the present disclosure.

FIG. 8 is a schematic diagram of a structure corresponding to a step B109 of a manufacturing method of a display panel according to embodiments of the present disclosure.

FIG. 9 is a schematic diagram of a display apparatus according to embodiments of the present disclosure.

### DETAILED DESCRIPTION

Technical proposals in the embodiments of the present disclosure will be clearly and completely described with reference to the accompanying drawings in the embodiments of the present disclosure, and it is obvious that the described embodiments are only a part of the embodiments of the present disclosure, but not all the embodiments. Based on the embodiments in the present disclosure, all other embodiments obtained by those skilled in the art without creative work belong to the scope of protection of the present disclosure. Furthermore, it is to be understood that the detailed description described herein is for illustration and explanation only, and is not intended to limit the present disclosure. In the present disclosure, the various embodiments may be combined with each other but will not be described one by one. Unless otherwise stated, orientational terms such as “upper” and “lower” generally refer to the upper and lower in the actual use or working state of the device, specifically the drawing direction in the drawings. The terms “inside” and “outside” are for the outline of the device. The terms “first”, “second”, “third” etc. are configured for indicative purposes only and do not impose numerical requirements or establish order.

Embodiments of the present disclosure provide a display panel and a display apparatus, which will be described in detail below. Note that the order of description of the following embodiments is not intended to limit the preferred order of the embodiments.

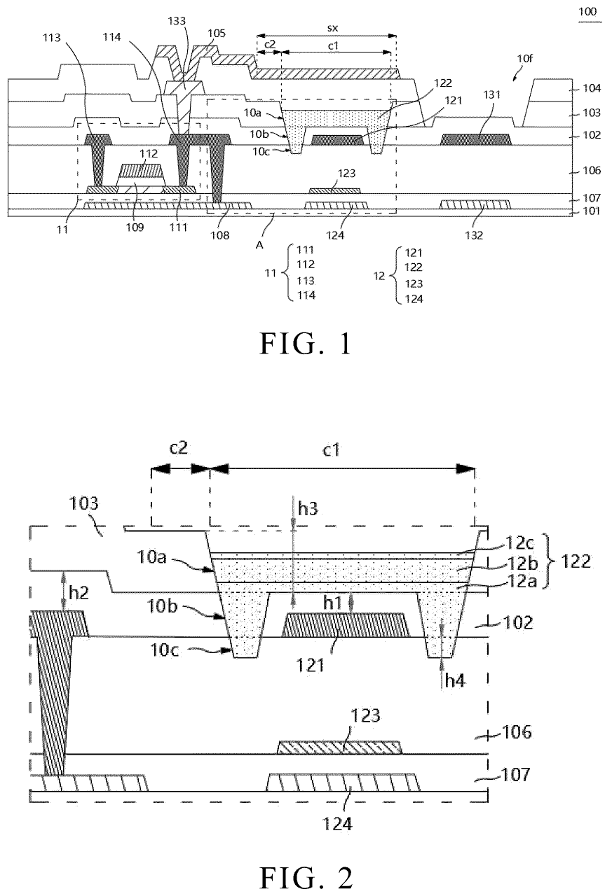

Referring to FIG. 1 and FIG. 2, embodiments of the present disclosure provide a display panel 100 including a pixel area sx configured to emit light. The display panel 100 includes a substrate 101, a thin film transistor 11, a capacitor structure 12, a first insulating layer 102, a first planarization layer 103, a second planarization layer 104, and an anode 105.

The thin film transistor 11 is disposed on substrate 101. The capacitor structure 12 is disposed on the substrate 101 and at least a portion of the capacitor structure 12 is located within the pixel area sx. The capacitor structure 12 includes a first electrode plate 121 and a second electrode plate 122 disposed in different layers, and the second electrode plate 122 is located on one side of the first electrode plate 121 away from the substrate 101.

The first insulating layer 102 covers the thin film transistor 11 and is located between the first electrode plate 121 and the second electrode plate 122. A thickness h1 of the first insulating layer 102 at a position corresponding to the first electrode plate 121 is less than a thickness h2 of the first insulating layer 102 at a position corresponding to the thin film transistor 11.

The first planarization layer 103 covers the first insulating layer 102. The first planarization layer 103 is provided with a first opening 10a corresponding to the first electrode plate 121, and the second electrode plate 122 is filled in the first opening 10a. A thickness of the second electrode plate 122 is less than or equal to a depth h3 of the first opening 10a. The second planarization layer 104 covers the first planarization layer 103 and the second electrode plate 122 and fills the first opening 10a.

The anode 105 is disposed on one side of the second planarization layer 104 away from the substrate 101 and is electrically connected to the thin film transistor 11. In a thickness direction of the display panel 100, the anode 105 and capacitor structure 12 are partially overlapped.

In the display panel 100 of the embodiments of the present disclosure, on the basis that the first insulating layer 102 covers the thin film transistor 11 and is located between the first electrode plate 121 and the second electrode plate 122 of the capacitor structure 12, by thinning the thickness of the first insulating layer 102 at the position corresponding to the capacitor structure 12, a distance between the first electrode plate 121 and the second electrode plate 122 is shortened to improve a capacitance value of the capacitor structure 12 while lowering a terrain of a capacitor structure area c1. In order to partially thin the first insulating layer 102, the first opening 10a is defined in the first planarization layer 103 corresponding to the capacitor structure 12. A thickness of the first planarization layer 103 is relative large, so that the terrain of the capacitor structure area c1 is lowered more. Thus, by filling the second electrode plate 122 in the first opening 10a, the terrain of the capacitor structure area c1 and a terrain of a non-device area c2 are better balanced, and at the same time the capacitance value of the capacitor structure 12 is increased.

It should be understood that the capacitor structure 12 includes at least three electrode plates. A third electrode plate 123 is disposed on one side of the first electrode plate 121 close to the substrate 101. In this way, an arrangement of the second electrode plate 122 can not only improve the capacitance value of the capacitor structure 12, but also smooth the terrain difference between the capacitor structure area c1 and the non-device area c2.

It should be explained that the non-device area c2 refers to an area in which devices and traces are not provided, that is, an area in which only the substrate and insulating layers are included in the thickness direction of the display panel 100. Furthermore, the pixel area sx refers to an area formed by a boundary of the opening defined in the pixel definition layer exposing the anode 105, and a light-emitting material is provided in the opening.

In addition, it should be noted that since the second electrode plate 122 is formed by ink-jet printing, the inside of the second electrode plate 122 has a certain porosity, and the porosity of the second electrode plate 122 is greater than a porosity of the first electrode plate 121 and a porosity of the anode 105. In combination with the first opening 10a, when the display panel 100 is applied to a curved display panel, the first opening 10a and the second electrode plate 122 with larger porosity have better stress release performance, and the reliability of the curved display panel is improved.

Optionally, the second electrode plate 122 includes a plurality of conductive particles, and the plurality of conductive particles are connected to each other to form the second electrode plate 122.

Optionally, a material of a light-emitting layer may be an organic material, such as Alq3, bis (2-methyl-8-hydroxyquinolin-N1, O8)-(1, 1′-biphenyl-4-hydroxyl) aluminum (BAlq), DPVBi, Almq3, or 3-tert-butyl-9, 10-bis (2-naphthalene) anthracene (TBADN).

The material of the light-emitting layer may be an inorganic material, and may be, for example, one or more selected from group IV semiconductor nanocrystals, group II-V semiconductor nanocrystals, group II-VI semiconductor nanocrystals, group IV-VI semiconductor nanocrystals, group III-V semiconductor nanocrystals, and group III-VI semiconductor nanocrystals. Examples thereof include one or more of silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots, indium arsenide quantum dots, gallium nitride quantum dots, and the like.

That is, the display panel 100 of the embodiments of the present disclosure may be an electroluminescent panel such as an organic light-emitting display panel, a quantum dot light-emitting display panel, or a micro-LED display panel.

Optionally, in some embodiments of the present disclosure, the first insulating layer 102 is provided with a first groove 10b communicated with the first opening 10a, and the first groove 10b is located at least on one side of the first electrode plate 121.

A part of the second electrode plate 122 extends to fill the first groove 10b and is disposed opposite to the side of the first electrode plate 121.

It can be understood that in the thickness direction of the display panel 100, the first groove 10b and the first opening 10a are communicated with each other, so that the material of the second electrode plate 122 can fill the first groove 10b and the first opening 10a, and while making up for the segment difference, an overlapping area of the second electrode plate 122 and the first electrode plate 121 is increased, thereby increasing the capacitance value of the capacitor structure 12.

It should be understood that the second electrode plate at this time is attached to side walls and bottom walls of the first groove 10b and the first opening 10a to form a concave-convex structure, as compared with the second electrode plate formed by vapor deposition. In the embodiments of the present disclosure, the second electrode plate 122 is formed by ink-jet printing, and based on the formation method of ink-jet printing, the second electrode plate 122 has better leveling property, and can fill the first groove 10b and the first opening 10a while maintaining better flatness, thereby improving the flatness of the capacitor structure area c1.

Secondly, the second electrode plate 122 is formed by ink-jet printing, so that the thickness of the second electrode plate 122 can be flexibly adjusted by setting the size of ink droplets and the number of times of printing to better balance the terrain difference between the capacitor structure area c1 and the non-device area c2. In addition, the electrical properties of the capacitor structure 12 can be adjusted by adjusting a conductive material of the ink droplets, thereby improving the heat dissipation, load and conductivity of the capacitor structure 12.

Optionally, in some embodiments of the present disclosure, the display panel 100 further includes an interlayer dielectric layer 106, and the interlayer dielectric layer 106 is disposed on the side the first electrode plate 121 close to the substrate 101.

A second groove 10c is defined in the interlayer dielectric layer 106. The first groove 10b is a through groove penetrating the first insulating layer 102. The second groove 10c communicates with the first groove 10b. A part of the second electrode plate 122 extends to fill the second groove 10c.

It will be appreciated that the arrangement of the second groove 10c is such that the part of the second electrode plate 122 extends into the interlayer dielectric layer 106 to maintain the maximum overlap between the second electrode plate 122 and the side of the first electrode plate 121, increasing the capacitance value of the capacitor structure 12.

Secondly, the arrangement of the first groove 10b and the second groove 10c causes the part of the second electrode plate 122 to extend in a direction towards the substrate 101, locally increasing a thickness of the second electrode plate 122, thereby reducing the impedance of the second electrode plate 122.

Optionally, in some embodiments of the present disclosure, a depth h4 of the second groove 10c is less than ⅓ of a thickness of the interlayer dielectric layer 106.

It can be understood that, on the basis that the second groove 10c and the partially thinned first insulating layer 102 are formed through the same light mask, in order to avoid excessive thinning of the first insulating layer 102, which would result in a short circuit between the first electrode plate 121 and the second electrode plate 122, the depth of the second groove 10c should not be too deep, for example, the depth h4 of the second groove 10c is ⅓, ¼, ⅕, ⅙, 1/7, ⅛, 1/9, or 1/10 of the thickness of the interlayer dielectric layer 106.

Optionally, in some embodiments of the present disclosure, the second electrode plate 122 is a single film layer structure.

Optionally, in some embodiments of the present disclosure, the second electrode plate 122 includes a first transparent conductive part 12a and a metal reflective layer 12b disposed on one side of the first transparent conductive part 12a away from the substrate 101. The first transparent conductive part 12a is provided in the first groove 10b and the second groove 10c, and the metal reflective layer 12b is provided in the first opening 10a.

It can be understood that since the second electrode plate 122 is formed by ink-jet printing, a multi-layer stacked structure of the second electrode plate 122 is formed by multiple printing, and the multiple printing method can make up for the terrain defect due to a previous printing by a latter printing, thereby improving the flatness of the second electrode plate 122. Secondly, the metal reflective layer 12b is positioned on one side of the first transparent conductive part 12a close to the anode 105, so that the metal reflective layer 12b is closer to the anode 105, so as to reflect the light transmitted through the anode 105 more quickly, and improve the light emission efficiency of the pixel. On the other hand, since the first transparent conductive part 12a is located on one side of the metal reflective layer 12b close to the substrate 101, a risk of corrosion of the metal reflective layer 12b can be reduced.

Optionally, the conductivity of the metal reflective layer 12b is greater than the conductivity of the first transparent conductive part 12a.

Optionally, in some embodiments of the present disclosure, the second electrode plate 122 further includes a second transparent conductive part 12c, and the second transparent conductive part 12c is disposed on one side of the metal reflective layer 12b away from the substrate 101.

It can be understood that the second transparent conductive part 12c is provided to cover the metal reflective layer 12b, so as to reduce the risk of corrosion of the metal reflective layer 12b.

Optionally, a material of the first transparent conductive part 12a and a material of the second transparent conductive part 12c are same, and both of them are metal oxides. A material of the metal reflective layer 12b may be silver, aluminum, magnesium, or the like.

Optionally, in some embodiments of the present disclosure, a surface roughness of one side of the electrode plate 122 close to the anode 105 is greater than a surface roughness of the anode 105.

It can be understood that since the second electrode plate 122 includes the metal reflective layer 12b and the surface roughness of the second electrode plate 122 is relatively large, the light reflected by the metal reflective layer 12b can be diffusely reflected, and the light emission uniformity of the pixel area sx is improved. Since the second electrode plate 122 is formed by ink-jet printing, when a solvent is volatilized, a surface of the second electrode plate 122 naturally forms a concave-convex micro-structure, thus forming a rough surface of the second electrode plate 122, and no additional surface treatment process is required.

Optionally, in some embodiments, the second transparent conductive part 12c may also be formed by directly oxidizing one side of the metal reflective layer 12b away from the substrate 101 to reduce the thickness of the second electrode plate 122.

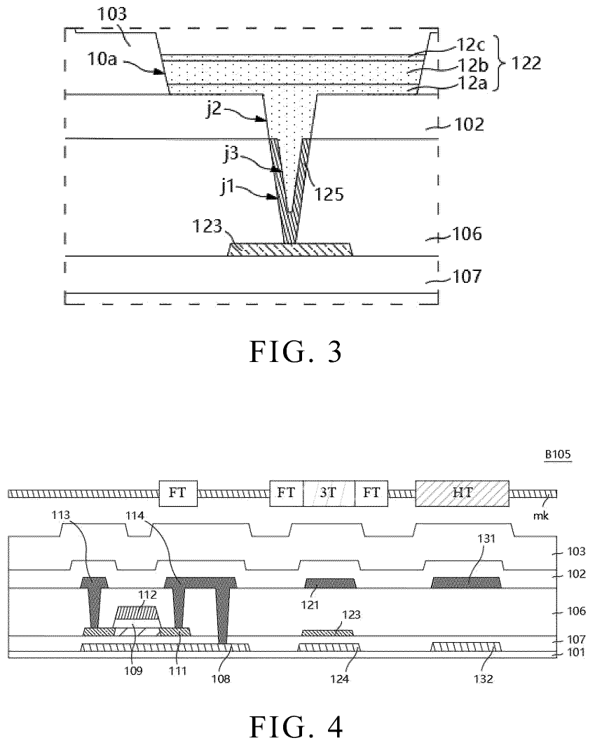

Optionally, with reference to FIG. 3, in some embodiments of the present disclosure, the capacitor structure 12 further includes a third electrode plate 123, and the third electrode plate 123 is disposed on one side of the interlayer dielectric layer 106 close to the substrate 101. The interlayer dielectric layer 106 is provided with a first contact hole j1 exposing the third electrode plate 123, and the first contact hole j1 is covered by a metal portion 125 which is connected to the third electrode plate 123. The metal portion 125 extends along a hole wall of the first contact hole j1, and a recessed groove j3 is defined on a side of the metal portion 125 away from the substrate 101.

The first insulating layer 102 is provided with a second contact hole j2 communicating with the recessed groove j3, and a part of the second electrode plate 122 fills the second contact hole j2 and the recessed groove j3 and is connected to the metal portion 125.

It can be understood that the metal portion 125 is employed to cover the first contact hole j1, so as to reduce a contact impedance and connection conductivity of the second electrode plate 122 and the third electrode plate 123. Secondly, by arranging the metal portion 125 to cover the first contact hole j1, an excessive etching of the third electrode plate 123 can be avoided at the time of forming the second contact hole j2, and the second contact hole j2 is avoided to be too deep, thereby improving the performance of the capacitor structure 12.

Optionally, in some embodiments of the present disclosure, another first transparent conductive part 12a is provided in the second contact hole j2 and the recessed groove j3, and a material of the another first transparent conductive part 12a includes a metal oxide.

It can be understood that, based on the strong corrosion resistance of the metal oxide, the stability of the connection between the second electrode plate 122 and the first electrode plate 121 can be improved by using the first transparent conductive part 12a made of the metal oxide to connect the metal portion 125.

Optionally, in some embodiments of the present disclosure, the capacitor structure 12 further includes a third electrode plate 123 and a fourth electrode plate 124. The display panel 100 further includes a buffer layer 107, a light-shielding part 108, and a second insulating layer 109.

The fourth electrode plate 124 and the light-shielding part 108 are disposed on the substrate 101 in the same layer. The buffer layer 107 covers the fourth electrode plate 124 and the light-shielding part 108. The third electrode plate 123 and an active layer 111 of the thin film transistor 11 are disposed in the same layer on one side of the buffer layer 107 away from the substrate 101. The second insulating layer 109 is disposed between the active layer 111 of the thin film transistor 11 and a gate 112 of the thin film transistor 11. The interlayer dielectric layer 106 covers the gate 112 of the thin film transistor 11, the buffer layer 107, and the third electrode plate 123. A source 113 and a drain 114 of the thin film transistor 11 and the first electrode plate 121 are arranged in the same layer on one side of the interlayer dielectric layer 106 away from the substrate 101. The first insulating layer 102 covers the interlayer dielectric layer 106, the source 113 and the drain 114 of the thin film transistor 11, and the first electrode plate 121.

It will be appreciated that the arrangement of the fourth electrode plate 124 may increase the capacitance value of the capacitor structure 12. Secondly, the fourth electrode plate 124 and the light-shielding part 108 are arranged in the same layer, the third electrode plate 123 is arranged in the same layer as the active layer 111, and the first electrode plate 121 is arranged in the same layer as the source 113 and the drain 114, thereby reducing a thickness of the display panel 100 and saving mask manufacturing processes.

Secondly, a distance between the first electrode plate 121 and the third electrode plate 123 is equal to the thickness of the interlayer dielectric layer 106, that is, the first electrode plate 121 and the third electrode plate 123 are separated by only the interlayer dielectric layer 106, further thinning a terrain height of the capacitor structure 12, thereby balancing the terrain difference from the non-device area c2.

Optionally, in some embodiments, the display panel 100 further includes a first trace 131 disposed in the same layer as the first electrode plate 121 and a second trace 132 disposed in the same layer as the fourth electrode plate 124. Both the first trace 131 and the second trace 132 are provided in an encapsulation clearance area. It should be understood that the encapsulation clearance area refers to an area covered by an encapsulation layer. The first insulating layer 102 covers the first trace 131. The second planarization layer 104 is provided with a second opening 10f, and the second opening 10f runs through the first planarization layer 103 and corresponds to the encapsulation clearance area.

Optionally, in some embodiments, the display panel 100 further includes a converting wire 133, and the converting wire 133 is disposed between the first planarization layer 103 and the second planarization layer 104. One end of the converting wire 133 is connected to the anode 105, and the other end of the converting wire 133 is connected to the drain 114 of the thin film transistor 11.

Hereinafter, a manufacturing method of the display panel 100 in embodiments of the present disclosure will be described.

In a step B101, a light-shielding layer and a buffer layer 107 are sequentially formed on the substrate 101. The light-shielding layer includes the light-shielding part 108, the fourth electrode plate 124, and the second trace 132.

Optionally, the substrate 101 may be a rigid substrate or a flexible substrate. A material of the substrate 101 includes one of glass, sapphire, silicon, silicon dioxide, polyethylene, polypropylene, polystyrene, polylactic acid, polyethylene dicarboxylate, polyethylene terephthalate, polyethylene naphthalate, polycarbonate, polyethersulfone, aromatic fluorotoluene containing polyarylate, polycyclic olefin, polyimide, and polyurethane.

Optionally, the light-shielding layer may be an inorganic metal material having a single layer structure, such as Cr (chromium), Mo (molybdenum), Mn (manganese), or the like, or having a multilayer structure including a molybdenum-aluminum-molybdenum (Mo/Al/Mo) metal layer structure, an aluminum-molybdenum (Al/Mo) metal layer structure, or a molybdenum-copper (Mo/Cu) metal layer structure, including but not limited to the above materials.

Next, the manufacturing method proceeds to a step B102.

In the step B102, a semiconductor layer, the second insulating layer 109, and the gate 112 are sequentially formed on the buffer layer 107.

The semiconductor layer includes the active layer 111 and the third electrode plate 123. Optionally, a material of the semiconductor layer is a metal oxide, and the material may be, for example, an amorphous metal oxide material containing indium, gallium, or zinc.

The third electrode plate 123 and a source portion and a drain portion of the active layer 111 both have a conductive structure.

Next, the manufacturing method proceeds to a step B103.

In the step B103, the interlayer dielectric layer 106, a first metal layer, and the first contact hole j1 are sequentially formed on the gate 112.

Optionally, the first metal layer includes the source 113, the drain 114, the first electrode plate 121, the metal portion 125, and the first trace 131. The metal portion 125 covers the first contact hole j1.

Next, the manufacturing method proceeds to a step B104.

In the step B104, the first insulating layer 102 and the first planarization layer 103 are formed on the first metal layer.

Optionally, the interlayer dielectric layer 106, the buffer layer 107, the first insulating layer 102, and the second insulating layer 109 may be formed of a plurality of inorganic layers stacked in an alternating manner. For example, the interlayer dielectric layer 106, the buffer layer 107, the first insulating layer 102, and the second insulating layer 109 may be formed as a double layer formed by stacking inorganic layers including at least one of silicon oxide, silicon nitride, silicon oxynitride, aluminum oxide, magnesium oxide, and titanium oxide, or a plurality of layers formed by alternately stacking inorganic layers including at least one of silicon oxide, silicon nitride, silicon oxynitride, aluminum oxide, magnesium oxide, and titanium oxide. However, the present disclosure is not limited thereto, and the interlayer dielectric layer 106, the buffer layer 107, the first insulating layer 102, and the second insulating layer 109 may be formed as a single inorganic layer containing the above-described insulating material.

Furthermore, in one or more embodiments, the interlayer dielectric layer 106 may be made of an organic insulating material such as polyimide or the like.

Optionally, the thickness of the first insulating layer 102 is between 3000 angstroms and 4000 angstroms, such as 3000 angstroms, 3500 angstroms, or 4000 angstroms.

The first planarization layer 103 may be an organic transparent film layer, a material thereof may be, such as transparent photoresist, acrylic resin, epoxy resin, phenolic resin, polyamide resin, polyimide resin, or the like.

Optionally, a thickness of the first planarization layer 103 is between 2 microns and 2.5 microns, such as 2 microns, 2.1 microns, 2.2 microns, 2.3 microns, 2.4 microns, or 2.5 microns.

In the embodiments, the first planarization layer 103 is a transparent photoresist as an example, but the present disclosure is not limited thereto.

Next, the manufacturing method proceeds to a step B105.

Referring to FIG. 4, in the step B105, the first planarization layer 103 is subjected to exposure processing using a multi-tone or gray-scale mask mk. An via hole area for connecting the first metal layer and an area corresponding to the first groove 10b are subjected to exposure process through a full light transmitting opening FT, an area corresponding to the first opening 10a is subjected to exposure process through a first light-transmitting portion 3T, and an area corresponding to the second opening 10f is subjected to exposure process through a second light-transmitting portion HT. A light transmittance of the full light transmitting opening FT, a light transmittance of the second light transmitting portion HT, and a light transmittance of the first light transmitting portion 3T decreases in this order. It should be explained that the light transmittance of the full light transmitting opening FT is 100%.

Next, the manufacturing method proceeds to a step B106.

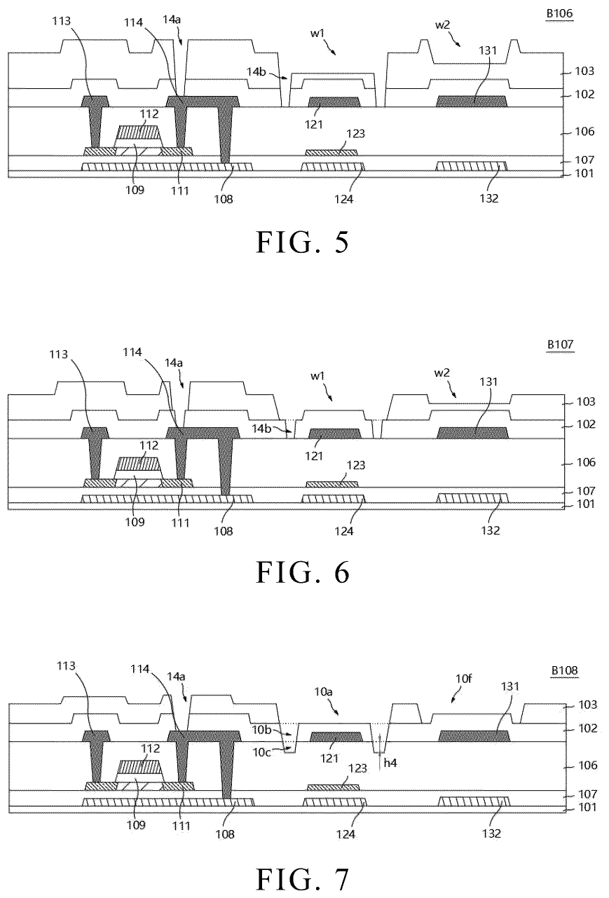

Referring to FIG. 5, in the step B106, a through hole 14a exposing the drain 114 and a second contact hole j2 exposing the metal portion 125 are defined in the first planarization layer 103. A first digging groove w1 is defined in an area corresponding to the first electrode plate 121, a through groove 14b is defined at an outer periphery of the first electrode plate 121, and a second digging groove w2 is defined in an area corresponding to the first trace 131. Both the through hole 14a and the through groove 14b penetrate the first planarization layer 103 and the first insulating layer 102. A depth of the first digging groove w1 is greater than a depth of the second digging groove w2.

Next, the manufacturing method proceeds to a step B107.

Referring to FIG. 6, in the step B107, the first planarization layer 103 is ashed, and the first planarization layer 103 is thinned to completely remove a part of the first planarization layer 103 directly above the first electrode plate 121, and a part of the first planarization layer 103 having a thinner thickness is retained directly above the first trace 131.

Next, the manufacturing method proceeds to a step B108.

Referring to FIG. 7, in the step B108, an exposed part of the first insulating layer 102 is etched to thin the part of the first insulating layer 102 corresponding to the first electrode plate 121.

Optionally, the thickness of the part of the first insulating layer 102 corresponding to the first electrode plate 121 is between 1000 angstroms and 2000 angstroms, such as 1000 angstroms, 1500 angstroms, or 2000 angstroms.

Optionally, the first planarization layer 103 and the first insulating layer 102 may be etched together by gas dry etching to form the first opening 10a, the second opening 10f, the first groove 10b, and the second groove 10c.

Optionally, the depth h4 of the second groove 10c is between 800 angstroms and 1200 angstroms, such as 800 angstroms, 900 angstroms, 1000 angstroms, 1100 angstroms, or 1200 angstroms.

Next, the manufacturing method proceeds to a step B109.

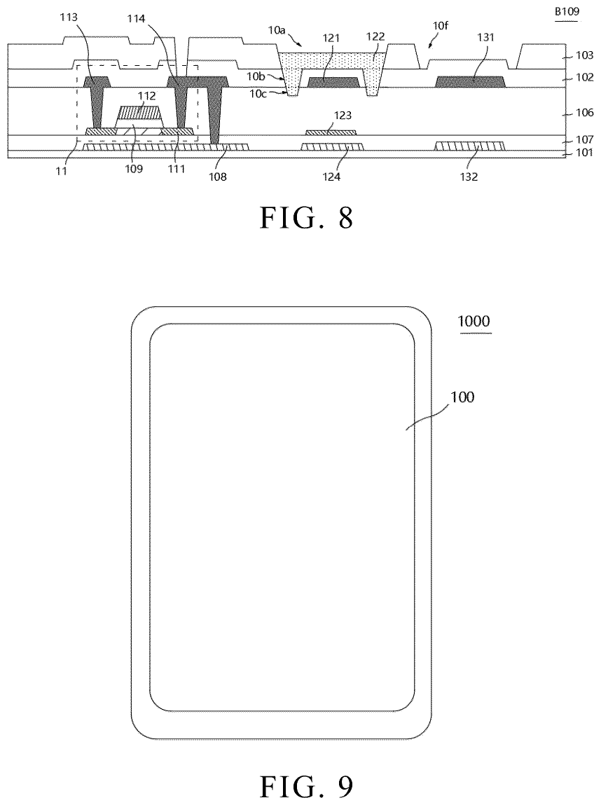

Referring to FIG. 8, in the step B109, a single or multilayer conductive filling layer(s) is(are) formed in the first opening 10a, the first groove 10b, and the second groove 10c by an ink-jet printing and vacuum drying process to form the second electrode plate 122.

Optionally, the conductive filling layer(s) in the first groove 10b and the second groove 10c may be a metal oxide, such as indium tin oxide, indium zinc oxide, or the like. That is, the first transparent conductive part 12a fills the first groove 10b and the second groove 10c and covers a bottom surface of the first opening 10a.

A material of the metal reflective layer 12b may be a single metal such as magnesium or silver or an alloy-based highly reflective material.

Next, the manufacturing method proceeds to a step B110.

In the step B110, the converting wire 133, the second planarization layer 104, and the anode 105 are sequentially formed on the first planarization layer 103.

Optionally, each of the gate 112, the first metal layer, and the converting wire 133 may be a metal element selected from chromium, copper, aluminum, gold, silver, zinc, molybdenum, tantalum, titanium, tungsten, manganese, nickel, iron, neodymium, and cobalt, or may be an alloy containing any of the above metal elements as a component, or an alloy containing any of the above metal elements in combination, or the like. Furthermore, the gate 112, the first metal layer, and the converting wire 133 may have a single-layer structure or a stacked structure of two or more layers.

A material of the second planarization layer 104 may be an organic transparent film layer such as a transparent photoresist, an acrylic resin, an epoxy resin, a phenolic resin, a polyamide resin, a polyimide resin, or the like.

The second planarization layer 104 covers the first planarization layer 103 and the first opening 10a to flatten an entire display area and improve the flatness of the capacitor structure area c1 and the non-device area c2.

It should be understood that the display panel 100 in the embodiments of the present disclosure further includes a pixel defining layer, a light-emitting functional layer, a cathode, and an encapsulation layer formed sequentially on the second planarization layer 104. An opening exposing the anode 105 is defined in the pixel definition layer, and the light-emitting functional layer is disposed in the opening.

Please refer to FIG. 9. Accordingly, embodiments of the present disclosure further provide a display apparatus 1000 including the display panel 100 as described in any one of the above embodiments.

It should be noted that a structure of the display panel 100 of the display apparatus 1000 according to the embodiments of the present disclosure is similar or the same as that of the display panel 100 according to any one of the above embodiments, and therefore, the description thereof will not be repeated here, and details can be referred to the relevant explanation of FIG. 1 to FIG. 8.

In the display apparatus 1000 of the embodiments of the present disclosure, on the basis that the first insulating layer 102 covers the thin film transistor 11 and is located between the first electrode plate 121 and the second electrode plate 122 of the capacitor structure 12, by thinning the thickness of the first insulating layer 102 at the position corresponding to the capacitor structure 12, a distance between the first electrode plate 121 and the second electrode plate 122 is shortened to improve a capacitance value of the capacitor structure 12 while lowering a terrain of a capacitor structure area c1. In order to partially thin the first insulating layer 102, the first opening 10a is defined in the first planarization layer 103 corresponding to the capacitor structure 12. A thickness of the first planarization layer 103 is relative large, so that the terrain of the capacitor structure area c1 is lowered more. Thus, by filling the second electrode plate 122 in the first opening 10a, the terrain of the capacitor structure area c1 and a terrain of a non-device area c2 are better balanced, and at the same time the capacitance value of the capacitor structure 12 is increased.

Optionally, the display apparatus 1000 may be applied to, and may be used within, various products including, for example, televisions, notebook computers, monitors, billboards, Internet of Things devices, and portable electronic devices including mobile phones, smartphones, tablet personal computers, mobile communication terminals, electronic notepads, electronic books, portable multimedia players, navigation, and ultra-mobile personal computers.

Furthermore, the display apparatus 1000 according to some embodiments may be applied to, and may be used within, wearable devices including smart watches, watch phones, glasses type displays, and head mounted displays. Furthermore, according to some embodiments, the display apparatus 1000 may be applied to an instrument panel for an automobile, a display screen for a center instrument panel of an automobile or a central information display arranged on the instrument panel, an interior mirror display instead of a side mirror of an automobile, and a display of an entertainment system arranged on the back of a front seat for a rear seat passenger in an automobile.

The display panel and display apparatus provided by the embodiments of the present disclosure are described in detail above, and the principles and implementations of the present disclosure are described herein by applying specific examples, and the description of the above embodiments is only used to help understand the methods and core ideas of the present disclosure. Meanwhile, those skilled in the art may change the specific embodiments and the scope of application according to the ideas of the present disclosure, and in summary, the contents of the present specification should not be construed as limiting the present disclosure.

What is claimed is:

1. A display panel, comprising a pixel area configured to emit light, and comprising:
a substrate;
a thin film transistor disposed on the substrate;
a capacitor structure disposed on the substrate, wherein at least a portion of the capacitor structure is located within the pixel area, the capacitor structure comprises a first electrode plate and a second electrode plate disposed in different layers, and the second electrode plate is located on one side of the first electrode plate away from the substrate;
a first insulating layer covering the thin film transistor and located between the first electrode plate and the second electrode plate, wherein a thickness of the first insulating layer at a position corresponding to the first electrode plate is less than a thickness of the first insulating layer at a position corresponding to the thin film transistor;
a first planarization layer covering the first insulating layer, wherein the first planarization layer has a first opening corresponding to the first electrode plate, the second electrode plate is filled in the first opening, and a thickness of the second electrode plate is less than or equal to a depth of the first opening;
a second planarization layer covering the first planarization layer and the second electrode plate and filling the first opening; and
an anode disposed on one side of the second planarization layer away from the substrate and electrically connected to the thin film transistor, wherein the anode partially overlaps the capacitor structure in a thickness direction of the display panel.

2. The display panel according to claim 1, wherein the first insulating layer is provided with a first groove communicated with the first opening, and the first groove is located at least on one side of the first electrode plate; and
a part of the second electrode plate extends to fill the first groove and is disposed opposite to the side of the first electrode plate.

3. The display panel according to claim 2, further comprising an interlayer dielectric layer disposed on one side of the first electrode plate close to the substrate,
wherein the interlayer dielectric layer is provided with a second groove, the first groove is a through groove penetrating the first insulating layer, the second groove communicates with the first groove, and a part of the second electrode plate extends to fill the second groove.

4. The display panel according to claim 3, wherein a depth of the second groove is less than ⅓ of a thickness of the interlayer dielectric layer.

5. The display panel according to claim 3, wherein the second electrode plate comprises a first transparent conductive part and a metal reflective layer disposed on one side of the first transparent conductive part away from the substrate, the first transparent conductive part is disposed in the first groove and the second groove, and the metal reflective layer is disposed in the first opening.

6. The display panel according to claim 5, wherein a conductivity of the metal reflective layer is greater than a conductivity of the first transparent conductive part.

7. The display panel according to claim 5, wherein the second electrode plate further comprises a second transparent conductive part disposed on one side of the metal reflective layer away from the substrate.

8. The display panel according to claim 7, wherein a material of the first transparent conductive part and a material of the second transparent conductive part are same.

9. The display panel according to claim 5, wherein the capacitor structure further comprises a third electrode plate disposed on one side of the interlayer dielectric layer close to the substrate, the interlayer dielectric layer is provided with a first contact hole exposing the third electrode plate, the first contact hole is covered by a metal portion connected to the third electrode plate, the metal portion extends along a hole wall of the first contact hole, and a recessed groove is formed on one side of the metal portion away from the substrate; and
the first insulating layer is provided with a second contact hole communicating with the recessed groove, and a part of the second electrode plate fills the second contact hole and the recessed groove and is connected to the metal portion.

10. The display panel according to claim 9, wherein the second electrode plate further comprises another first transparent conductive part disposed in the second contact hole and the recessed groove, and a material of the another first transparent conductive part comprises a metal oxide.

11. The display panel according to claim 1, wherein a surface roughness of the second electrode plate close to the anode is greater than a surface roughness of the anode.

12. The display panel according to a claim 3, wherein the capacitor structure further comprises a third electrode plate and a fourth electrode plate, and the display panel further comprises a buffer layer, a light-shielding part, and a second insulating layer; and
the fourth electrode plate and the light-shielding part are arranged on the substrate in a same layer, the buffer layer covers the fourth electrode plate and the light-shielding part, the third electrode plate and an active layer of the thin film transistor are arranged in a same layer on one side of the buffer layer away from the substrate, the second insulating layer is disposed between the active layer of the thin film transistor and a gate of the thin film transistor, the interlayer dielectric layer covers the gate of the thin film transistor, the buffer layer, and the third electrode plate, a source and a drain of the thin film transistor and the first electrode plate are arranged in a same layer on one side of the interlayer dielectric layer away from the substrate, the first insulating layer covers the interlayer dielectric layer, the source and the drain of the thin film transistor, and the first electrode plate.

13. The display panel according to claim 12, wherein a distance between the first electrode plate and the third electrode plate is equal to a thickness of the interlayer dielectric layer.

14. The display panel according to claim 12, further comprising a first trace disposed in a same layer as the first electrode plate and a second trace disposed in a same layer as the fourth electrode plate, wherein both the first trace and the second trace are provided in an encapsulation clearance area.

15. The display panel according to claim 1, further comprising a converting wire disposed between the first planarization layer and the second planarization layer, wherein an end of the converting wire is connected to the anode, and another end of the converting wire is connected to a drain of the thin film transistor.

16. A display apparatus, comprising a display panel according to claim 1.
